(19) United States
(12) Patent Application Publication
(10) Pub. No.: US 2026/0355908 A1
(43) Pub. Date: Nov. 12, 2026

(54) DEVICE AND METHOD FOR HOLDING A WORKPIECE

(71) Applicant: NOVA LTD., Rehovot (IL)

(72) Inventors: Alex Shichtman, Rehovot (IL); Rami DADABYEV, Rehovot (IL); Nimrod HAR NOY, Rehovot (IL); Elik CHEN, Rehovot (IL); Roi RINGEL, Rehovot (IL); Dmitry KALININ, Rehovot (IL); Avi OSTERKO, Rehovot (IL)

(73) Assignee: NOVA LTD., Rehovot (IL)

(21) Appl. No.: 19/139,359

(22) PCT Filed: Dec. 15, 2022
(86) PCT No.: PCT/IL2022/051335

§ 371 Date: Jun. 15, 2025

(51) Int. Cl. B25B 11/00; B23Q 3/08

(52) U.S. Cl. CPC B25B 11/005; B23Q 3/088; B23Q 2703/04

(57) ABSTRACT

A workpiece holding device and method are disclosed. The device comprises (1) a vacuum chuck having a base formed with one or more main vacuum ports, an array of spaced-apart support members, and an annular rim projecting at a perimeter portion of the base, wherein said rim and said array of spaced-apart projecting support members define together a workpiece support surface; and (2) an annular resilient sealing member articulated external to the annular rim defining a confined secondary space between the annular resilient sealing member and the annular rim of the vacuum chuck, wherein the annular sealing member is configurable for sealingly engaging with a peripheral portion of a workpiece placeable over the vacuum chuck, thereby enabling the confined space to operate as a peripheral auxiliary vacuum chamber.

### TECHNOLOGICAL FIELD

The disclosure generally relates to devices and methods for holding a workpiece, and particularly for holding and flattening of workpieces.

### BACKGROUND

Vacuum chucks are devices commonly used to hold various types of workpieces/articles. For example, vacuum chucks can be used to hold semiconductor wafers during inspection (metrology) or during other periods of wafer manufacturing. Vacuum chucks typically have a chucking surface that contacts the wafer. One or more vacuum pads extend through this chucking surface. Suction forces retain a wafer on the vacuum chuck when air other gas is evacuated through the vacuum pads such that a pressure difference between the chucking surface and opposing wafer surface holds the wafer in place during processing.

During manufacture, a large number of semiconductor devices are typically formed on the same semiconductor wafer. The term “Wafer” is a generic term for silicon, ceramic or compound materials which contain the desired semiconductor circuit. A wafer typically consists of a multiple patterned thin layers of semiconductor materials, with an upper surface onto which bonds may be attached. Wafers may be provided as round, circular, wafers, or as square or rectangular wafers that are sometimes referred to as “panels”. In the present document, the term “wafer” should be taken to include wafers of any shape, e.g., round and polygonal.

Due to the thin dimensions (thickness) of semiconductor wafers, warping of wafers is a common problem experienced in wafer handling. Warping may cause a wafer to deform into a non-flat/non-planar shape that results in difficulties for further processing, particularly where wafer handling systems are automated. In semiconductor applications using metrology systems, some wafers may be warped to such an extent that these warped wafers cannot be properly processed or further handled by an inspection/metrology system. Such wafers may be warped as a result of upstream manufacturing processes (e.g., metal deposition) that change the planar flatness and cause these wafers to be bowl-shaped, dome-shaped, or asymmetrical (twisted).

Warped wafers present a challenge, as the flatness of the wafer surface affects how well a vacuum chuck can secure a wafer. The warp of the wafer can prevent the vacuum system/chuck from maintaining sufficient seal between the chuck and the underside of the wafer. More specifically, when the wafer is severely warped, the wafer does not uniformly cover the vacuum channels of the chuck due to the tendency of the wafer edges to flex upwards, away from the chuck surface, or undesirably releasing the wafer from the chuck during operation. This results in large vacuum leaks that reduce the clamping force exerted by each vacuum channel. In many scenarios, the reduced clamping force is unable to achieve adequate force levels required to pull the wafer from its deformed shape down onto the chuck. As a result, the wafer chuck is unable to adequately constrain the wafer and further processing of the wafer is not possible without additional intervention thus affecting wafer handling and impair wafer inspection/processing.

Some wafer holding devices known from the patent literature are briefly described hereinbelow.

U.S. Pat. No. 5,805,408 discloses an electrostatic clamping apparatus with lip seal for holding substrates in a vacuum processing chamber. The apparatus includes an electrostatic clamp, a sealing member surrounding the electrostatic clamp, and an edge ring surrounding the sealing member and holding the sealing member in place against the electrostatic clamp. The sealing member provides a seal between the electrostatic clamp and the substrate. This seal prevents the leakage of temperature control gas into the processing chamber and prevents process gas from reaching the electrostatic clamp and/or causing arcing in the chamber.

U.S. Pat. No. 6,771,482 discloses an apparatus having a sealing member extending around the periphery of a substrate support or chuck, seals an individual substrate with respect to a substrate support, typically in a processing chamber. The seal is of a corrugated shape, that enhances clamping forces, typically from electrostatic or mechanical clamps, to provide a seal between it and the substrate.

U.S. Pat. No. 10,468,288 discloses methods and systems for vacuum mounting a warped, thin substrate onto a flat chuck are presented herein. A vacuum chuck includes three or more collapsible bellows that move above the chuck and into contact with a warped substrate. The bellows seal and vacuum clamp onto the backside surface of the substrate. As the substrate moves toward the chucking surface, the extensible sealing element extends at least five millimeters above the chuck body and into contact with the substrate. As the space between the chuck and the substrate is evacuated, the extensible sealing element collapse into the recessed annular channel, and the substrate is clamped onto the flat chucking surface of chuck body.

WO 2020/076949 discloses a vacuum clamping apparatus for supporting a warped semiconductor wafer comprises a vacuum chuck which has a chuck surface for supporting the wafer and a lip seal which surrounds a first portion of the chuck surface. A justifier is configured to press the wafer onto the chuck surface, so that the lip seal contacts the underside of the wafer and forms a seal between the underside of the wafer and the first portion of the chuck surface. A vacuum source in fluid communication with the first portion of the chuck surface, for applying vacuum suction to attract the wafer onto the chuck surface.

### GENERAL DESCRIPTION

There is a need in the art for improved devices and techniques for proper holding and aligning/flattening a workpiece (e.g., a semiconductor wafer) to be inspected/processed and for securing the workpiece in an inspection/processing plane, particularly such delicate article as a semiconductor wafer.

The embodiments disclosed herein provide a device/technique for holding and flattening a workpiece by vacuum while facilitating quick regulated release of the workpiece therefrom.

A vacuum chuck is disclosed having a substantially flat base equipped with an array of spaced-apart support members, one or more vacuum ports extending at the surface of the base; an annular rim projecting from the base and surrounding the support members and the one or more vacuum ports and defining a primary vacuum chamber; and a annular resilient sealing member externally surrounding the annular rim and spaced apart therefrom, defining therebetween an auxiliary/secondary space operating as and peripheral auxiliary vacuum chamber and sealingly secured to the base below the free ends of the support members and configured with a free resilient arm member extending above the free ends of the support members; and one or more vacuum outlets located at the auxiliary space.

Free ends the array of spaced-apart support members and an edge of the annular rim are coplanar and define together a workpiece support plane configured for supporting, securing and flattening a workpiece placeable over the vacuum chuck by vacuum for inspection and/or processing.

It is to be noted that the term “annular” should interpreted herein broadly and refers to a perimeter of any closed-loop shape including, inter alia, a circular/oval shape and any polygonal shape.

The annular resilient sealing member is configured to engage an underside of the workpiece above the workpiece support plane to form a preliminary vacuum chamber including the volumes of the primary and peripheral auxiliary vacuum chambers, and for bringing the workpiece from a plane located above the vacuum chuck onto the support plane of the chuck responsive to application of vacuum pressure via the one or more vacuum ports. The annular resilient sealing member is further configured to deform between an extended/relaxed state in which the annular resilient sealing member engages the workpiece in a plane above the chuck to form the preliminary vacuum chamber, and a deformed/retracted state in which the workpiece is forced by the vacuum pressure into the support plane, and thereby secured by vacuum on top of the support members and the annular rim.

In the deformed/retracted state of the deformable/elastic member the workpiece engages the annular rim to thereby form the primary and peripheral vacuum chambers. In order to maintain/hold the workpiece, in its flattened form, on the support plane where inspection/processing may be carried out, the vacuum pressure in the peripheral auxiliary vacuum chamber is at least partially released through the one or more vacuum outlets after the workpiece engages the annular rim, to thereby reduce the surface area of the workpiece experiencing the vacuum pressure, remove attraction forces acting on the deformable/elastic member due to the vacuum pressure. After processing of the workpiece is completed, the workpiece is in a release-standby state, ready to be pushed upwardly upon at least partially releasing the vacuum pressure from the primary vacuum chamber to facilitate quick regulated release of workpiece.

The at least one resilient arm member is configured to engage the underside of the workpiece and thereby least partially seal the preliminary vacuum chamber. For example, in a chuck designed to clamp circular wafers, the resilient arm member is preferably provided in a form of ring-shaped/circular arm member, encircling the various components of the vacuum chuck. In a chuck designed for clamping square wafers, or “panels”, the resilient lip is preferably provided as a square, the sides/faces of the square extending around and enclosing the vacuum chuck.

Thus, according to one broad aspect of the of the presently disclosed subject matter, there is provided a workpiece holding device. The workpiece holding device includes a vacuum chuck including a base formed with one or more main vacuum ports extending at a surface of the base, an array of spaced-apart support members projecting from a face of the base, and an annular rim projecting at a perimeter portion of the base. The rim and said array of spaced-apart projecting support members define together a workpiece support surface.

The workpiece holding device also includes an annular resilient sealing member articulated external to said annular rim and below the support surface defining a confined secondary space between said annular resilient sealing member and the annular rim of the vacuum chuck. The annular sealing member is configurable for sealingly engaging with a peripheral portion of a workpiece placeable over the vacuum chuck, thereby enabling the confined space to operate as a peripheral auxiliary vacuum chamber.

In some embodiments, the annular resilient sealing member is deformable between an extended position wherein at least an edge of said annular resilient sealing member extends above the workpiece support surface, and a deformed position wherein the edge of the annular resilient sealing member extends at or below the workpiece support surface.

In some embodiments, the annular resilient sealing member in its extended position is configured to engage said workpiece along its periphery in a plane above said support surface, and in its deformed position it is configured to bring the workpiece to said support plane.

In some embodiments, the annular resilient sealing member comprises at least one resilient arm member defining the confined secondary space between the at least one arm member and the annular rim of the vacuum chuck.

In some embodiments, the at least one resilient arm is configured for sealingly engaging with a peripheral portion of the workpiece placeable over the vacuum chuck.

In some embodiments, the annular resilient sealing member is configured to undergo the deformation by application of vacuum.

In some embodiments, the annular resilient sealing member is further configured for providing planarity of the workpiece being held by the chuck by the application of the vacuum.

In some embodiments, the annular resilient sealing member is configured to at least partially seal a volume defined between the workpiece and the base of the chuck.

In some embodiments, the base of the chuck and an interior of the annular resilient sealing member define a primary volume therebetween, the volume forms a primary vacuum chamber.

In some embodiments, the annular resilient sealing member in its extended position and the workpiece define a preliminary volume configured to operate as a preliminary vacuum chamber. The preliminary volume includes the peripheral auxiliary vacuum chamber and the primary vacuum chamber.

In some embodiments, the base of the chuck includes one or more auxiliary ports located along the circumference of the vacuum chuck external to the annular rim and configured to enable buildup of vacuum within the peripheral auxiliary vacuum chamber and regulated release of the vacuum pressure conditions therefrom.

In some embodiments, the annular resilient sealing member is configured to return to its extended position upon at least partially releasing of vacuum in the peripheral auxiliary vacuum chamber and the primary vacuum chamber to thereby bring the workpiece to the plane above said support surface.

In some embodiments, the annular resilient sealing member is configured to return to its extended position upon initially at least partially releasing vacuum in the peripheral auxiliary vacuum chamber and thereafter in the primary vacuum chamber to thereby bring the workpiece to the plane above the said support surface.

In some embodiments, the annular resilient sealing member includes a base portion by which said annular resilient sealing is articulated externally to the vacuum chuck.

In some embodiments, the annular resilient sealing member defines a closed-loop structure having at least partially corrugated cross-section geometry.

In some embodiments, the annular resilient sealing member defines a closed-loop structure having Z-like cross-section geometry.

In some embodiments, the annular resilient sealing member defines a closed-loop structure having zigzag-like cross-section geometry.

In some embodiments, the annular resilient sealing member includes a base portion connectable to the chuck base external to the annular rim of the chuck.

In some embodiments, the at least one resilient lip and the base portion are connected by a closed loop side portion, said side portion defines at least one substantially V-shaped groove enabling deformation of the annular resilient sealing member from the extended to deformed position by vacuum.

In some embodiments, the support plane is substantially parallel to the chuck base. In some embodiments, the annular resilient sealing member comprises Fluor-elastomer material.

According to another broad aspect of the of the presently disclosed subject matter, there is provided a workpiece holding system. The workpiece holding system includes the workpiece holding device described above and a vacuum source coupleable to the primary and the secondary spaces.

In some embodiments, the workpiece holding system includes a plurality of robotic arms configured for holding the workpiece at a plane above the workpiece holding device.

According to yet another broad aspect of the of the presently disclosed subject matter, there is provided a method for positioning a workpiece. The method includes placing a workpiece on an annular resilient sealing member such that said annular resilient sealing member sealingly engages a periphery of said workpiece. The annular resilient sealing member being sealingly articulated to a base of a vacuum chuck to define a peripheral vacuum chamber external to a peripheral rim of said vacuum chuck. The rim confines a primary vacuum chamber and defines a workpiece support plane extending thereabove.

The method further includes applying vacuum in said primary and peripheral vacuum chambers, to thereby change said annular sealing member into a retracted state bringing said workpiece onto said support plane, and partition between said primary and peripheral vacuum chambers and at least partially releasing the vacuum pressure form said peripheral vacuum space for releasing pressure conditions acting on the annular sealing member.

In some embodiments, the application of vacuum in the primary and peripheral vacuum spaces vacuum is configured for providing planarity of the workpiece.

In some embodiments, the method further includes maintaining said annular sealing member in the retracted state and processing and/or inspecting the workpiece while held pressed onto the support plane.

In some embodiments, the method further includes releasing the vacuum form primary and peripheral vacuum chambers to thereby returning the annular resilient sealing member to the extended position and pushing the workpiece to a plane above the support plane.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1A-1E schematically illustrate different views of a workpiece holding device according to some possible embodiments, wherein FIG. 1A shows a top view of the workpiece holding device, FIG. 1B shows a perspective view of the workpiece holding device, FIG. 1C shows a side view of the workpiece holding device, and FIGS. 1D-1E show cross-sectional views of the holding device holding a workpiece W;

FIGS. 2A-2C schematically illustrate different views of a vacuum chuck according to some possible embodiments, wherein FIG. 2A shows a top view of the vacuum chuck, FIG. 2B shows a perspective view of the vacuum chuck, and FIG. 2C shows a side view of the vacuum chuck;

FIGS. 3A-3D schematically illustrate different views of a annular resilient sealing member according to some possible embodiments, wherein FIG. 3A shows a top view of the annular resilient sealing member, FIG. 3B shows a perspective view of the annular resilient sealing member, FIG. 3C shows a side view of the annular resilient sealing member;

FIGS. 4A to 4F illustrate stages of positioning and holding of a workpiece procedure according to some possible embodiments;

FIG. 5 is a flowchart illustrates steps of a procedure for positioning and holding of a workpiece schematically illustrated in FIGS. 4A to 4F;

FIGS. 6A and 6B schematically illustrate, respectively, top and side views of a holding device system according to some possible embodiments.

### DETAILED DESCRIPTION OF EMBODIMENTS

The various embodiments of the present application are described below with reference to the drawings, which are to be considered in all aspects as illustrative only and not restrictive in any manner. In effort to provide a concise description of these embodiments, not all features of an actual implementation are described in the specification. Elements illustrated in the drawings are not necessarily to scale, or in correct proportional relationships, which are not critical. Emphasis instead being placed upon clearly illustrating the principles of the disclosed subject matter to allow persons skilled in the art to make and use it, once they understand its principles.

For an overview of several example features, process stages, and principles of the invention, the examples of workpiece holding devices/techniques illustrated schematically and diagrammatically in the figures are intended for effectively securing and flattening workpieces (e.g., semiconductor wafers) on the device. These workpiece holding devices/techniques are shown as one example implementation that demonstrates a number of features, processes, and principles used for proper holding of a workpiece to be inspected/processed and securing the workpiece on an inspection plane, but they are also useful for other applications and can be made in different variations. Therefore, this description will proceed with reference to the shown examples, but with the understanding that the invention recited in the claims below can also be implemented in myriad other ways and embodiments without departing from the essential characteristics described herein, once the principles are understood from the descriptions, explanations, and drawings herein. All such variations, as well as any other modifications apparent to one of ordinary skill in the art and useful in workpiece holding applications may be suitably employed and are intended to fall within the scope of this disclosure.

As used herein, the phrase “for example,” “such as”, “for instance” and variants thereof describe non-limiting embodiments of the presently disclosed subject matter. Reference in the specification to “one case”, “some cases”, “other cases” or variants thereof means that a particular feature, structure, or characteristic described in connection with the embodiment(s) is included in at least one embodiment of the presently disclosed subject matter. Thus, the appearance of the phrase “one case”, “some cases”, “other cases” or variants thereof does not necessarily refer to the same embodiment(s).

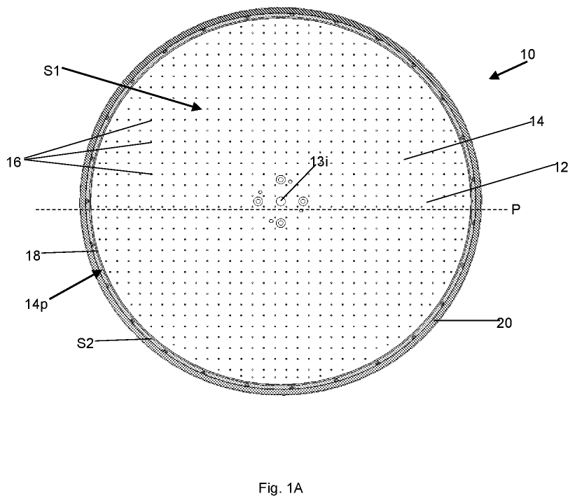

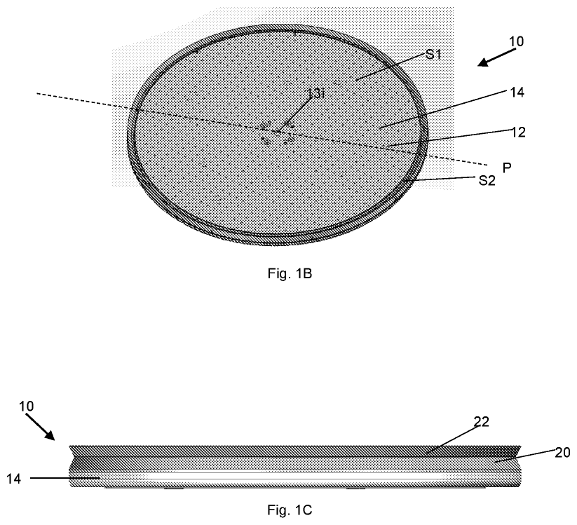

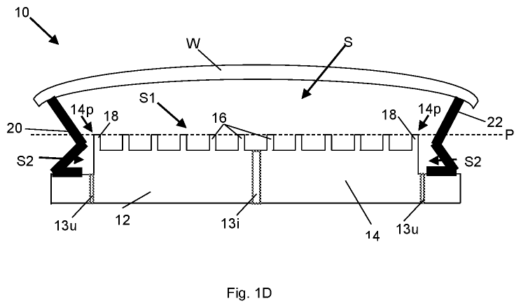

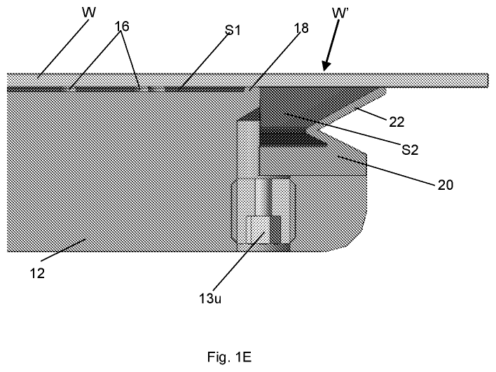

Reference is made to FIGS. 1A-1E schematically illustrate different views of a workpiece holding device 10 according to some possible embodiments. In particular, FIGS. 1A-1C show respectively, a top, perspective and side views of the workpiece holding device 10 and FIG. 1D-1E show cross-sectional views of the holding device 10 associated with a workpiece W. The holding device 10 includes vacuum chuck 12 adapted for supporting a workpiece W (e.g., a semiconductor wafer). The vacuum chuck 12 is provided with a base 14, being substantial flat and faces the workpiece W to be held. The base 14 includes one or more main vacuum ports 13i extending at a surface of the base 14, an array of spaced-apart support members (e.g., pins or ribs), generally at 16, projecting from a face of the base 14 and an annular rim 18 projecting at a perimeter portion 14p of the base 14.

As best seen in FIG. 1D, free ends of the spaced-apart support members 16 and an edge of the annular rim 18 are coplanar (i.e., project/extend to the same predetermined distance above the chuck base 14) such that they define together a workpiece support surface P at which the workpiece is to be clamped and flattened (e.g., for inspection) by vacuum. The annular rim 18 and the face of the base 14 define a confined primary space S1 configured to operate as a primary vacuum chamber.

The holding device 10 also includes an annular resilient sealing member 20 articulated/coupled to the vacuum chuck 12 externally to the annular rim 18, and in some preferred embodiments below the support surface P (the free ends of the support members 16) such that annular resilient sealing member 20 surrounds the peripheral annular rim 18 of the chuck 12 to define/form a confined auxiliary/secondary space S2 therebetween configured to operate as a peripheral auxiliary vacuum chamber upon engagement of the annular resilient sealing member 20 with the workpiece W, as better seen in FIG. 1D.

The annular resilient sealing member 20 is configured for engaging an underside of the workpiece W to from a preliminary space S between them operating as a preliminary vacuum chamber including the primary and secondary spaces S1 and S2, and for bringing/drawing the workpiece W to the support surface P in response to vacuum pressure. More specifically, the annular resilient sealing member 20 is deformable between an extended/relaxed state position in which it engages the workpiece W (e.g., along its periphery) in a plane above said workpiece support surface P and a retracted/deformed state in which the workpiece W is pressed onto the support surface P and maintained therein by vacuum on top of the support members 16 and the annular rim 18.

Optionally, and in some embodiments preferably, the annular resilient sealing member 20 is also configured to provide for planarity of the workpiece W being held by the chuck 12, by the application of the vacuum, i.e., enabling transition of the workpiece from its initial non-planar (bowed or warped) shape to a planar shape thereof, as exemplified in FIG. 1E. Optionally, and in some embodiments preferably the annular resilient sealing member 20 is configured to operate in a spring-like manner as will be described further below in detail.

As better seen in FIG. 1E, the annular resilient sealing member 20 is equipped with at least one arm member 22 such that the secondary space S2 is defined between the at least the one arm member 22 and the annular rim 18. The at least one arm member 22 is configured for sealingly engaging with a peripheral portion W′ of the workpiece W at a plane above the vacuum chuck 12, and also above the support surface P, thereby confining the secondary space S2 between the at least one arm member 22 and the annular rim 18 of the vacuum chuck 12 so as to enable its operation as the peripheral auxiliary vacuum chamber. In some embodiments, in the extended position/state of the annular resilient sealing member 20, an edge of the at least one arm member 22 extends above the support surface P, and in the deformed position/state of the annular resilient sealing member 20, the edge of the at least one arm member 22 is retracted to or below the workpiece support surface P.

As shown in FIGS. 1D and 1E, the vacuum chuck 12 can also include one or more auxiliary ports 13u located along a circumference of the vacuum chuck 12 e.g., outward to the annular rim 18. For example, in some embodiments the auxiliary ports 13u fluidly communicate to the secondary space S2 and extend to some portion in the bottom (or side) of the chuck base 14. As shown in the FIG. 1D, in some embodiments the auxiliary ports 13u pass/protrude through a circumferential support portion of chuck base 14.

The one or more auxiliary ports 13u are configured for enabling buildup/applying of fluid (e.g., air) vacuum pressure conditions within the peripheral auxiliary vacuum chamber (defined by the secondary space S2), and/or regulated release of vacuum pressure conditions therefrom. As better seen in FIG. 1E, in the deformed state of the annular resilient sealing member 20 the workpiece W is forced onto the support members 16 and the annular rim 18, to thereby seal the primary and secondary spaces S1 and S2, and to thereby form two independent/separated vacuum chambers.

Particularly, the primary and auxiliary vacuum chambers defined, respectively, by the sealed primary and secondary space S1 and S2 are configured to hold and flatten the workpiece W onto the support surface P, e.g., for processing and/or inspecting the workpiece W. In some embodiments, the primary and auxiliary vacuum chambers are configured for at least partially releasing the vacuum pressure therefrom simultaneously/concurrently via the one or more main vacuum outlets 13i and/or the auxiliary ports 13u to thereby enable quick release of the of the annular resilient sealing member 20 to its extended state and quick release of the workpiece W from the chuck. In some embodiments, the one or more the auxiliary ports 13u are configured for enabling buildup of temporal vacuum pressure conditions within the peripheral auxiliary vacuum chamber, and regulated release of vacuum pressure conditions therefrom. In this regard, the peripheral auxiliary vacuum chamber defined by the secondary space S2 is configured to at least partially release the vacuum pressure therein via the one or more auxiliary ports 13u, while the workpiece W is maintained/anchored on the workpiece support surface P by the vacuum pressure conditions continuously maintained in the primary vacuum chamber (S1). In this case, the vacuum pressure is initially at least partially released from the peripheral auxiliary chamber defined by the secondary space S2, and thereafter from the primary vacuum chamber This way the pressure on the annular resilient sealing member 20 and the peripheral portion W′ of the workpiece W can be reduced/released, to thereby facilitate quick/regulated release of the of the of the annular resilient sealing member 20 to its extended state and quick/regulated of the workpiece W from the chuck upon releasing thereafter of the vacuum pressure conditions in the primary vacuum chamber defined by the sealed primary space S1.

Accordingly, in some embodiments the auxiliary ports 13u are used for applying/building up the vacuum pressure conditions in the peripheral auxiliary vacuum chamber and releasing of the same therefrom. In other possible embodiments the auxiliary ports 13u are used only for releasing the vacuum pressure conditions from the peripheral auxiliary vacuum chamber after it is being generated/built up in the primary vacuum chamber via the main vacuum ports 13i.

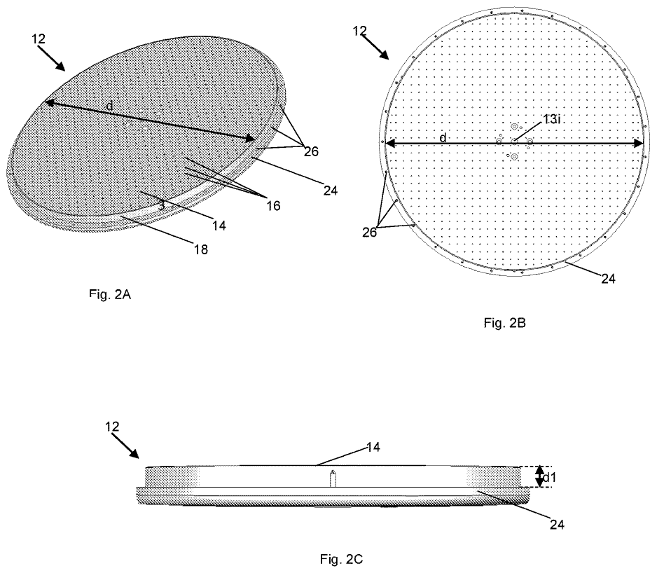

Reference is made to FIGS. 2A-2C schematically illustrate, respectively, a top, perspective, side views of the vacuum chuck 12 according to some possible embodiments. The vacuum chuck 12 has a predetermined diameter d which can be in the range of 50-450 mm, determined in accordance with the size of the workpiece (typical wafers today are of 200 or 300 mm diameter. As shown, the spaced-apart support members 16 may be uniformly distributed over the surface of the base 14 however other arrangements are also contemplated. As mentioned above, the spaced-apart support members 16 and the annular rim 18 can extend/project to a predetermined distance above the chuck base 14.

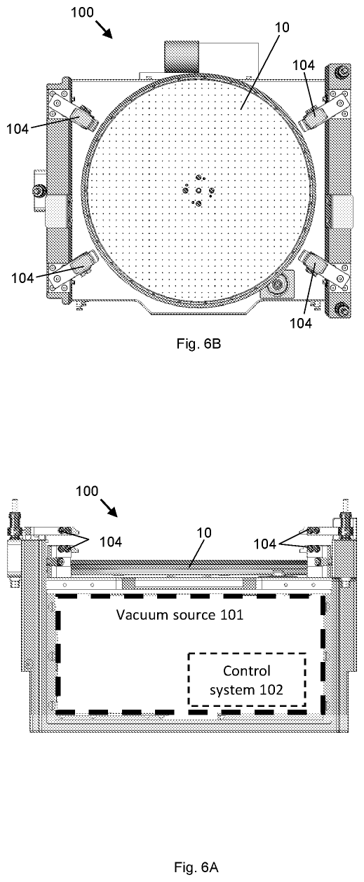

The at least one main vacuum port 13i can be centered in the chuck base 14 and configured for allowing suction of fluid (e.g., air) therethrough for enabling buildup of fluid vacuum pressure conditions within the primary vacuum chamber (defined by the primary space S1 in FIGS. 1D and 1E), and regulated release of vacuum pressure conditions therefrom. To this end, the vacuum chuck 12 may be associated with vacuum means such as an external vacuum source coupleable to the primary and secondary spaces (S1 and S2 in FIG. 1D) as shown further below with reference to FIGS. 6A and 6B. It should be mentioned that although one such vacuum hole in the center of the chuck base is shown in the figures, in general, more than one vacuum hole may be provided and may be located at various locations on the chuck base.

In some embodiments, the vacuum chuck 12 includes an integral support 24 extending along a circumference of the vacuum chuck 12 and, a better seen in FIG. 2B, located at a certain distance d1 below the support surface P. The integral support 24 is configured for supporting the annular resilient sealing member (20 in FIGS. 1A-1C) thereon. The integral support 24 can be provided with an arrangement of space apart holes/orifices 26 configured for receiving coupling means, e.g., screws or bolts, therewithin for articulating the sealing member to the vacuum chuck 12.

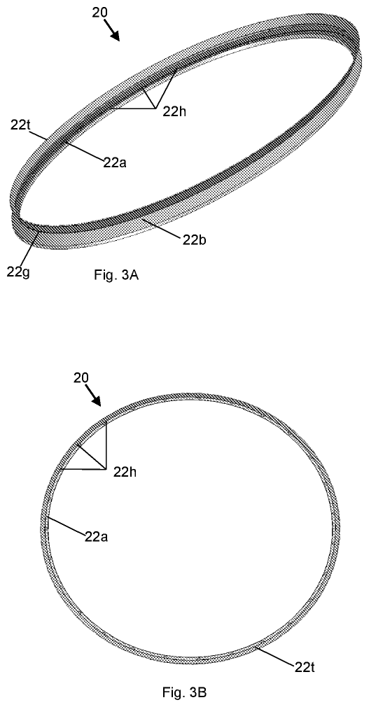

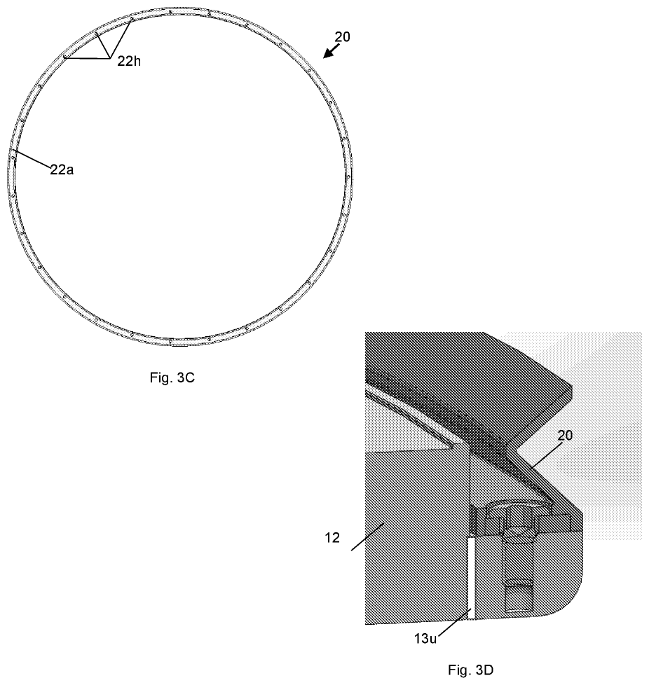

Reference is made to FIGS. 3A-3D schematically illustrate, respectively, a top, perspective, side views of the annular resilient sealing member 20 according to some possible embodiments. The annular resilient sealing member 20 exemplified in the has a Z-like cross-sectional geometry. As shown, the annular resilient sealing member 20 includes a top resilient arm member 22t, bottom resilient arm member 22b and a base portion 22a by which the annular resilient sealing member 20 can be articulated to the integral support 24 of the chuck base 14. The top and bottom resilient arm members 22t and 22b are connected by a closed loop side portion 22g defining V-shaped groove enabling deformation of the annular resilient sealing member 20 from the extended to deformed position by vacuum.

The base portion 22a has a plurality of spaced-apart holes 22h for receiving coupling means, e.g., screws or bolts. As shown in FIG. 3D in a self-explanatory manner the base portion 22a can be connected/articulated to integral support (24 in FIGS. 1A-1C) via screws or bolts.

In some embodiments, the annular resilient sealing member 20 has a plurality of arm members to form a zigzagged-like cross-sectional geometry of the annular resilient sealing member 20. In some embodiments, the annular resilient sealing member 20 corrugated cross-sectional geometry.

In some embodiments, the annular resilient sealing member 20 is formed from resilient material including, inter alia, rubber or synthetic rubber such as Fluor-elastomer materials, so that the annular resilient sealing member 20 is resiliently deformable.

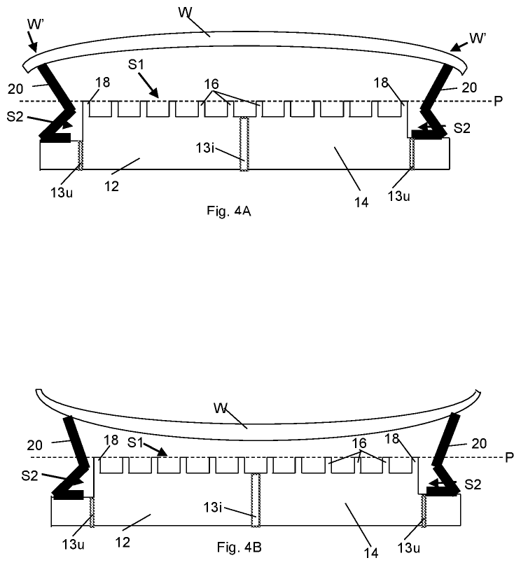

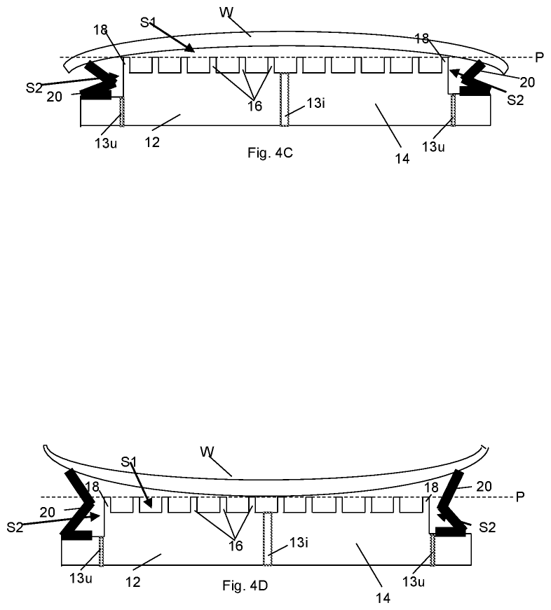

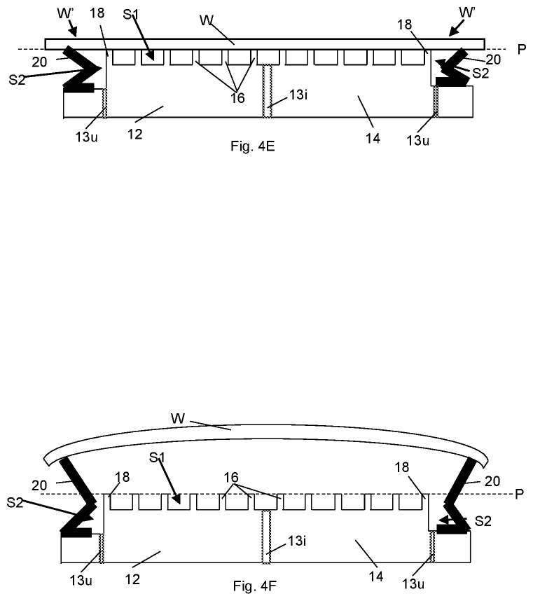

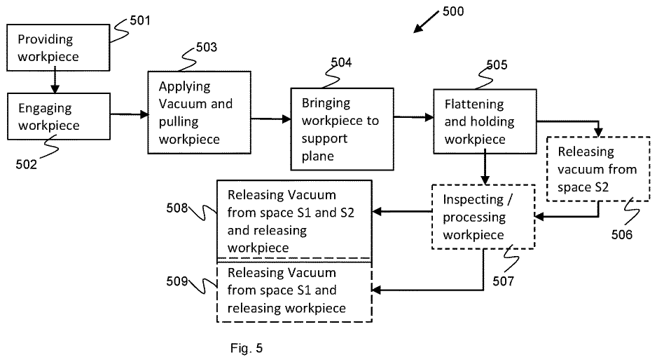

Reference is made to FIGS. 4A to 4F and to the flowchart of FIG. 5, illustrating stages procedure 500 for positioning and holding of a workpiece according to possible embodiments of the presently disclosed subject matter. In FIGS. 4A and 4B a workpiece W in its initial bowed/warped shape is provided (step 501) to the holding device 10. Two possible bowed shapes of the workpiece W are illustrated, a concave shape (FIG. 4A) and a convex shape (FIG. 4B), however the workpiece W may have other warped shapes. The warped workpiece W is then engaged (step 502) from its underside at the peripheral portion W′ of the workpiece and at a certain distance away from edges thereof by the annular resilient sealing member 20 to position the workpiece W on top of the annular resilient sealing member 20 at a plane above the vacuum chuck 12.

Then, vacuum suction is applied (step 503) via the one or more main vacuum ports 13i and, in some embodiments, also via the auxiliary ports 13u, e.g., simultaneously or in accordance with a certain time pattern, to the preliminary vacuum chamber, defined by the preliminary space S including the primary and secondary spaces S1 and S2 defining, respectively, the primary and the peripheral auxiliary vacuum chambers. The vacuum suction gives rise to attraction/pulling force being exerted on the workpiece W and on the annular resilient sealing member 20. In turn, the workpiece W applies pressing force on the annular resilient sealing member 20 that along with the attraction/pulling force causing the annular resilient sealing member 20 to deform to its retracted state/position and the workpiece W to be pulled/attracted from its initial position above the support surface P towards the support surface P thereby reducing distance of the workpiece W from the support plane P and reducing volume of the preliminary vacuum chamber.

It should be noted that the annular resilient sealing member 20 may be flexible and may generally operate in a spring like manner such that when it is being deformed it applies a resisting force (resisting the deformation) on the workpiece W. However, the attraction/pulling force, applied on the workpiece W and on the annular resilient sealing member 20 itself, dominate said resisting force thus enabling deformation of the annular resilient sealing member 20 and pulling/attraction of the workpiece W towards the support surface P.

In FIGS. 4C and 4D, the workpiece W is being brought to the support surface P (step 504). As shown in FIG. 4C, in case the wafer has a concave shape the wafer, as it reaches the support surface P it initially engages it initially engages the annular rim 18 and the annular resilient sealing member 20 is deformed/retraced to a plane below the support surface P. As shown in FIG. 4D, in case the workpiece W has a convex shape it initially engages at least some of the spaced-apart support members 16 and the annular resilient sealing member 20 is deformed/retraced to a plane above the support surface P. The workpiece W is then being pressed against the spaced-apart support members 16 and the annular rim 18 by the vacuum until it reaches its planar/flat form held on the support plane P (step 505) and the annular resilient sealing member 20 is deformed/retraced to a position at the support surface P.

In FIG. 4E, the flattened workpiece W is being held on the on the support surface P. As shown, the annular resilient sealing member 20 is deformed/retraced to the support surface P. As also shown, once the flattened workpiece W is pressed on the support surface P, two separate/independent vacuum chambers, defined respectively, by sealed primary and secondary spaces S1 and S2 are formed, forcing and maintaining the workpiece W to the support surface P. Then, processing/inspection (step 507) of the workpiece W may be carried out.

After processing of the workpiece is completed, the workpiece W is in a release-standby state, ready to be pushed upwardly in a spring-like manner upon at least partially releasing the vacuum pressure (step 508) from the primary vacuum chamber and the peripheral auxiliary vacuum chamber simultaneously or successively to facilitate quick release of workpiece W. In FIG. 4F vacuum pressure is at least partially released (step 508) from the primary and the peripheral auxiliary vacuum chambers and the annular resilient sealing member 20 is released from its deformed state to its extended (initial) state and pushes in a spring-like manner the workpiece W upwardly to its initial location above the support surface P in a spring-like manner.

In some embodiments, vacuum pressure in the primary and the peripheral auxiliary vacuum chambers can be released controllably/selectively (e.g., successively). In particular, prior to processing/inspection (step 507) of the workpiece W, vacuum pressure can be at least partially released (step 506) from the peripheral auxiliary vacuum chamber defined by the secondary space S2 so as to at least partially remove vacuum pressure forces from the resilient sealing member 20 and from the peripheral portion W′ of the flattened workpiece W while the space S1 continues to operate as the primary vacuum chamber thereby forcing and maintaining the flattened workpiece W on the support surface P and processing (step 507) of the workpiece W can be carried out., This way the peripheral portion W′ of the flattened workpiece W, which could otherwise deform due to strong attraction forces it could experience in this space, remains flattened. Once processing of the workpiece W is completed, vacuum pressure can be at least partially released (step 509) from the primary vacuum chamber to thereby facilitate quick/regulated release of the workpiece W from the chuck.

In some embodiments, vacuum suction in the preliminary vacuum chamber is performed only via the main vacuum ports 13i while the auxiliary ports 13u are used only for releasing the vacuum pressure conditions (by allowing passage of air therethrough) from the peripheral auxiliary vacuum chamber upon completion of processing/inspection of the workpiece W. In this case, during vacuum suction, air enters through the auxiliary ports 13u, however, the vacuum suction is much stronger thus generating/building up vacuum in the preliminary vacuum chamber (including the from the primary and the peripheral auxiliary vacuum chambers). Once the workpiece W is on the support surface P, air continues to enter to the auxiliary vacuum chamber defined by the sealed space S2 thereby at least partially releasing the vacuum therefrom while the workpiece W is forced/maintained flattened on the support surface P due to the vacuum maintained in the primary vacuum defined by sealed space S1. After the processing of the workpiece W is completed, vacuum pressure can be at least partially released from the primary vacuum chamber (space S1) to thereby facilitate quick/regulated release of the workpiece W from the chuck.

Reference is made to FIGS. 6A and 6B schematically illustrate, respectively, top and side views of a holding system 100 according to some possible embodiments. The holding device system 100 utilizes the holding device 10 and may include/associated with a vacuum source 101, which may be external, and a plurality of robotic arms 104 adapted for holding a workpiece above the holding device 10. The vacuum source 101 is fluidly coupled to the holding device 10, and more specifically to the to the primary space (S1 in FIG. 1D) extending between the surface of the base of the vacuum chuck and the workpiece support surface via the one or more vacuum pads (13i in FIG. 1D) and, in some embodiments, to the secondary space S2 via the auxiliary ports (13u in FIG. 1D).

In some embodiments, the vacuum source 101 includes/associated with a control system 102 configured and operable for releasing selectively (e.g., successively) or simultaneously vacuum pressure conditions in the primary and the peripheral auxiliary vacuum chambers.

It should be understood that throughout this disclosure, where a process or method is shown or described, the steps of the method may be performed in any order or simultaneously, unless it is clear from the context that one step depends on another being performed first. It is also noted that terms such as primary, main, secondary, first, second, etc. may be used to refer to specific elements disclosed herein without limiting, but rather to distinguish between the disclosed elements. Relative terms such as “lower,” “upper,” “horizontal,” “vertical,” “above,” “below,” “up,” “down,” “top” and “bottom”, as well as derivatives thereof (e.g., “horizontally,” “downwardly,” “upwardly,” etc.), and similar adjectives in relation to orientation of the described elements/components refer to the manner in which the illustrations are positioned on the paper, not as any limitation to the orientations in which these elements/components can be used in actual applications.

As described hereinabove and shown in the associated figures, the present disclosure provides workpiece holding devices/systems, and related methods. While particular embodiments of the invention have been described, it will be understood, however, that the invention is not limited thereto, since modifications may be made by those skilled in the art, particularly in light of the foregoing teachings. As will be appreciated by the skilled person, the invention can be carried out in a great variety of ways, employing more than one technique from those described above, all without exceeding the scope of the claims.

1. A workpiece holding device, comprising:
a vacuum chuck comprising a base formed with one or more main vacuum ports extending at a surface of the base, an array of spaced-apart support members projecting from a face of the base, and an annular rim projecting at a perimeter portion of said base, wherein said rim and said array of spaced-apart projecting support members define together a workpiece support surface; and
an annular resilient sealing member articulated external to said annular rim and below said support surface defining a confined secondary space between said annular resilient sealing member and the annular rim of the vacuum chuck, wherein said annular sealing member is configurable for sealingly engaging with a peripheral portion of a workpiece placeable over the vacuum chuck, thereby enabling said confined space to operate as a peripheral auxiliary vacuum chamber.

2. The device of claim 1 wherein the annular resilient sealing member is deformable between an extended position wherein at least an edge of said annular resilient sealing member extends above the workpiece support surface, and a deformed position wherein the edge of the annular resilient sealing member extends at or below the workpiece support surface.

3. The vacuum chuck device of claim 1, wherein the annular resilient sealing member in its extended position is configured to engage said workpiece along its periphery in a plane above said workpiece support surface, and in its deformed position it is configured to bring the workpiece to said workpiece support plane.

4. The device of claim 1, wherein the annular resilient sealing member comprises at least one resilient arm member defining the confined secondary space between said at least one arm member and the annular rim of the vacuum chuck.

5. The device of claim 4, the at least one resilient arm is configured for sealingly engaging with a peripheral portion of the workpiece placeable over the vacuum chuck.

6. The device of claim 2, wherein the annular resilient sealing member is configured to undergo the deformation by application of vacuum.

7. The device of claim 1, wherein annular resilient sealing is configured for providing planarity of the workpiece being held by the vacuum chuck by application of vacuum.

8. The device of claim 1, wherein the annular resilient sealing is configured to at least partially seal a volume defined between the workpiece and the base of the vacuum chuck.

9. The device of claim 1, wherein the base of the vacuum chuck and an interior of the annular resilient sealing member define a primary volume therebetween, said volume forms a primary vacuum chamber.

10. The device of claim 1, wherein the annular resilient sealing member in its extended position and the workpiece define a preliminary volume configured to operate as a preliminary vacuum chamber, said volume comprises the peripheral auxiliary vacuum chamber and the primary vacuum chamber.

11. The device of claim 1, wherein said base of the vacuum chuck comprises one or more auxiliary ports located along the circumference of the vacuum chuck external to the annular rim and configured to enable buildup of vacuum pressure within the peripheral auxiliary vacuum chamber and regulated release of the vacuum pressure therefrom.

12. The device of claim 2, wherein the annular resilient sealing member is configured to return to its extended position upon at least partially releasing of vacuum in the peripheral auxiliary vacuum chamber and the primary vacuum chamber to thereby bring the workpiece to the plane above said support surface.

13. The device of claim 2, wherein the annular resilient sealing member is configured to return to its extended position upon initially at least partially releasing of vacuum in the peripheral auxiliary vacuum chamber and thereafter in the primary vacuum chamber to thereby bring the workpiece to the plane above the said support surface.

14. The device of claim 1, wherein the annular resilient sealing member comprises a base portion by which said annular resilient sealing member is articulated externally to the vacuum chuck.

15. The device of claim 1, wherein the annular resilient sealing member defines a closed-loop structure having at least partially corrugated cross-section geometry.

16. The device of claim 1, wherein the annular resilient sealing member defines a closed-loop structure having Z-like cross-section geometry.

17. The device of claim 1, wherein the annular resilient sealing member defines a closed-loop structure having zigzag-like cross-section geometry.

18. The device of claim 1, wherein the annular resilient sealing member comprises a base portion connectable to the base external to the annular rim of the vacuum chuck.

19. The device of claim 4, wherein the at least one resilient arm member and the base portion are connected by a closed loop side portion, said side portion defines at least one substantially V-shaped groove enabling deformation of the annular resilient sealing member from the extended to deformed position by vacuum.

20. The device of claim 1, wherein the support plane is substantially parallel to the chuck base.

21. The device of claim 1, wherein the annular resilient sealing member comprises Fluor-elastomer material.

22. A method of positioning a workpiece, the method comprising:
placing a workpiece on an annular resilient sealing member such that said annular resilient sealing sealingly engages a periphery of said workpiece, said annular resilient sealing member being sealingly articulated to a base of a vacuum chuck to define a peripheral vacuum chamber external to a peripheral rim of said vacuum chuck, said rim confine a primary vacuum chamber and defines a workpiece support plane extending thereabove;
applying vacuum in said primary and peripheral vacuum chambers, to thereby change said annular sealing member into a retracted state bringing said workpiece onto said support plane, and partition between said primary and peripheral vacuum chambers; and
at least partially releasing the vacuum pressure form said peripheral vacuum space for releasing pressure conditions acting on said annular sealing member.

23. The method of claim 22, wherein the application of vacuum in said primary and peripheral vacuum spaces vacuum is configured for providing planarity of the workpiece.

24. The method of claim 22 further comprising maintaining said annular sealing member in the retracted state and processing and/or inspecting the workpiece while held pressed onto the support plane.

25. The method of claim 22 further comprises releasing the vacuum form primary and peripheral vacuum chambers to thereby returning the annular resilient sealing member to extended position and pushing the workpiece to a plane above the support plane.
